(19) United States
(12) Patent Application Publication
(10) Pub. No.: US 2025/0234758 A1
(43) Pub. Date: Jul. 17, 2025

(54) DISPLAY PANEL, MANUFACTURING METHOD THEREOF, AND DISPLAY DEVICE

(71) Applicant: Wuhan China Star Optoelectronics Semiconductor Display Technology Co., Ltd., Wuhan, Hubei (CN)

(72) Inventor: Feng XU, Wuhan, Hubei (CN)

(73) Assignee: Wuhan China Star Optoelectronics Semiconductor Display Technology Co., Ltd., Wuhan, Hubei (CN)

(21) Appl. No.: 18/579,382

(22) PCT Filed: Dec. 1, 2023
(86) PCT No.: PCT/CN2023/135822

§ 371 Date: Jan. 15, 2024

(30) Foreign Application Priority Data
Nov. 23, 2023 (CN) 202311581693.3

(51) Int. Cl. H10K 59/80; H10K 59/12

(52) U.S. Cl. CPC H10K 59/879; H10K 59/1201

(57) ABSTRACT

Disclosed are a display panel, a manufacturing method thereof, and a display device. A plurality of openings are provided in a first refractive index layer; a second refractive index layer is disposed at a side of the first refractive index layer away from a spacer layer; a refraction compensation portion is provided in the opening and between the second refractive index layer and the spacer layer, and a refractive index of the refraction compensation portion is less than that of the second refractive index layer, and the refractive index of the refraction compensation portion is less than that of the spacer layer.

### TECHNICAL FIELD

The present disclosure relates to a field of display technologies, and more particularly, to a display panel, a manufacturing method thereof, and a display device.

### BACKGROUND

In order to improve the luminous efficiency of the display panel, an organic layer having an opening is usually formed in the display panel, and then a high refractive index material is filled in the opening of the organic layer to change the light propagation path, so that light originally diverged at a large viewing angle is converged to a positive viewing angle, thereby improving the luminance of the positive viewing angle.

Currently, a high refractive index film layer may be formed on the organic layer by bonding, to fill the opening. Further, in the manufacturing process, since the display panel may undergo a plurality of processes such as handling, flipping, cutting, and slitting, after the opening is formed in the organic layer and the high refractive index film layer is bonded to the organic layer, a protective film is usually bonded to the organic layer, and the protective film is torn off when the high refractive index film layer is subsequently bonded to the organic layer.

However, in a process of peeling off the protective film, an adhesive layer on the protective film is prone to form a residue in a part of the opening of the organic layer, and because the refractive index of the adhesive layer is small, an optical anomaly, such as uneven display, appears on the display panel.

### SUMMARY

An embodiment of the present disclosure provides a display panel, a manufacturing method thereof, and a display device, which may improve an optical abnormality caused by residual adhesive layer.

An embodiment of the present disclosure provides a display panel including:
a substrate;
a light-emitting functional layer disposed at a side of the substrate, the light-emitting functional layer including a plurality of light-emitting portions;
a spacer layer disposed at a side of the light-emitting functional layer away from the substrate;
a first refractive index layer disposed at a side of the spacer layer away from the light-emitting functional layer, the first refractive index layer being provided with a plurality of openings corresponding to the plurality of light-emitting portions; and
a second refractive index layer disposed at a side of the first refractive index layer away from the spacer layer and filled within at least a plurality of the openings, a refractive index of the first refractive index layer being less than a refractive index of the second refractive index layer;
the display panel further includes a refraction compensation portion disposed in an opening of the plurality of openings, the refraction compensation portion is disposed between the second refractive index layer and the spacer layer, a refractive index of the refraction compensation portion is less than the refractive index of the second refractive index layer, and the refractive index of the refraction compensation portion is less than a refractive index of the spacer layer.

According to the above object of the present disclosure, an embodiment of the present disclosure further provides a method of manufacturing a display panel, including:
forming a light-emitting functional layer on a substrate, a plurality of light-emitting portions are formed in the light-emitting functional layer;
forming a spacer layer on a side of the light-emitting functional layer away from the substrate;
forming a first refractive index layer and a refraction compensation portion at a side of the spacer layer away from the light-emitting functional layer, a plurality of openings corresponding to the plurality of light-emitting portions are formed in the first refractive index layer, the refraction compensation portion is formed in the openings, and the refraction compensation portion has a refractive index less than a refractive index of the spacer layer; and
forming a second refractive index layer at a side of the first refractive index layer away from the spacer layer, the second refractive index layer filling the plurality of the openings, a refractive index of the first refractive index layer being less than a refractive index of the second refractive index layer, the refraction compensation portion being located between the spacer layer and the second refractive index layer, and the refractive index of the refraction compensation portion being less than the refractive index of the second refractive index layer.

According to the above object of the present disclosure, an embodiment of the present disclosure further provides a display device including a display panel including:
a substrate;
a light-emitting functional layer disposed at a side of the substrate, the light-emitting functional layer including a plurality of light-emitting portions;
a spacer layer disposed at a side of the light-emitting functional layer away from the substrate;
a first refractive index layer disposed at a side of the spacer layer away from the light-emitting functional layer, the first refractive index layer being provided with a plurality of openings corresponding to the plurality of light-emitting portions; and
a second refractive index layer disposed at a side of the first refractive index layer away from the spacer layer and filled within at least a plurality of the openings, a refractive index of the first refractive index layer being less than a refractive index of the second refractive index layer;
the display panel further includes a refraction compensation portion disposed in an opening of the plurality of openings, the refraction compensation portion is disposed between the second refractive index layer and the spacer layer, a refractive index of the refraction compensation portion is less than the refractive index of the second refractive index layer, and the refractive index of the refraction compensation portion is less than a refractive index of the spacer layer.

### DESCRIPTION OF DRAWINGS

FIG. 1 is a schematic structural diagram of a display panel according to a related art;

FIGS. 2 to 4 are schematic structural diagrams of a manufacturing process of a display panel according to a related art;

FIG. 5 is a schematic structural diagram of a display panel according to an embodiment of the present disclosure;

FIG. 6 is another schematic structural diagram of a display panel according to an embodiment of the present disclosure;

FIG. 7 is another schematic structural diagram of a display panel according to an embodiment of the present disclosure;

FIG. 8 is another schematic structural diagram of a display panel according to an embodiment of the present disclosure;

FIG. 9 is a flowchart of a method for manufacturing a display panel according to an embodiment of the present disclosure; and

FIGS. 10 and 11 are schematic structural diagrams of a manufacturing process of a display panel according to an embodiment of the present disclosure.

### DETAILED DESCRIPTION

Technical solutions in embodiments of the present disclosure will be clearly and completely described below in conjunction with drawings in the embodiments of the present disclosure. Obviously, the described embodiments are only a part of embodiments of the present disclosure, rather than all the embodiments. Based on the embodiments in the present disclosure, all other embodiments obtained by those skilled in the art without creative work fall within the protection scope of the present disclosure.

The following description provides various embodiments or examples for implementing various structures of the present disclosure. To simplify the description of the present disclosure, parts and settings of specific examples are described as follows. Certainly, they are only illustrative, and are not intended to limit the present disclosure. Further, in the present disclosure, reference numerals and reference letters may be repeated in different examples, which is for purposes of simplicity and clarity and does not indicate a relationship of the various embodiments and/or the settings. Furthermore, the present disclosure provides specific examples of various processes and materials, however, applications of other processes and/or other materials may be appreciated by those skilled in the art.

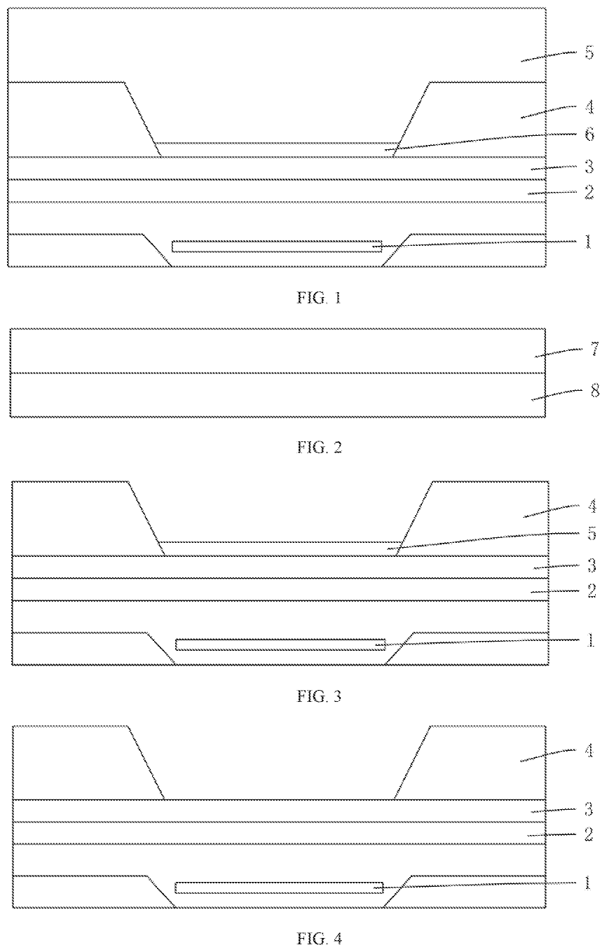

Referring to FIGS. 1 to 4, a display panel according to a related art includes a light-emitting layer 1, a touch layer 2 disposed above the light-emitting layer 1, an insulating layer 3 disposed on the touch layer 2, an organic layer 4 disposed on the insulating layer 3, and a high refractive index layer 5 disposed on the organic layer 4. An opening corresponding to the light-emitting layer 1 is provided in the organic layer 4, and the high refractive index layer 5 is filled in the opening, so that a light output path of the display panel can be changed at an inner wall of the opening by a total reflection principle to improve light-emitting efficiency. However, in the process, an opening may be formed in the organic layer 4, and then a plurality of processes such as handling, flipping, cutting, and slitting may be required. Therefore, it is necessary to cover the organic layer 4 using a protective layer 7 with an adhesive layer 8, which is positioned between the protective layer 7 and the organic layer 4 to protect the display panel, and the protective layer 7 and the adhesive layer 8 are peeled off in a subsequent process to adhere the high refractive index layer 5 to the organic layer 4. When the protective layer 7 and the adhesive layer 8 are peeled off, the adhesive layer 8 may remain because of the adhesive property of the adhesive layer 8, and form an adhering layer 6 the opening of the organic layer 4. Since the adhering layer 6 is not formed in each opening (i.e., the adhering layer 6 is formed in some areas, the adhering layer 6 is not formed in some areas), and the refractive index of the adhering layer 6 is low, when the light passes through the area with the adhering layer 6 and the area without the adhering layer 6, the refractive index changes are different, resulting in the optical path of the area with the adhesive layer 6 and the optical path of the area without the adhesive layer 6 being different, so that optical differences occur between the different areas, and the phenomenon of uneven display occurs in the display panel.

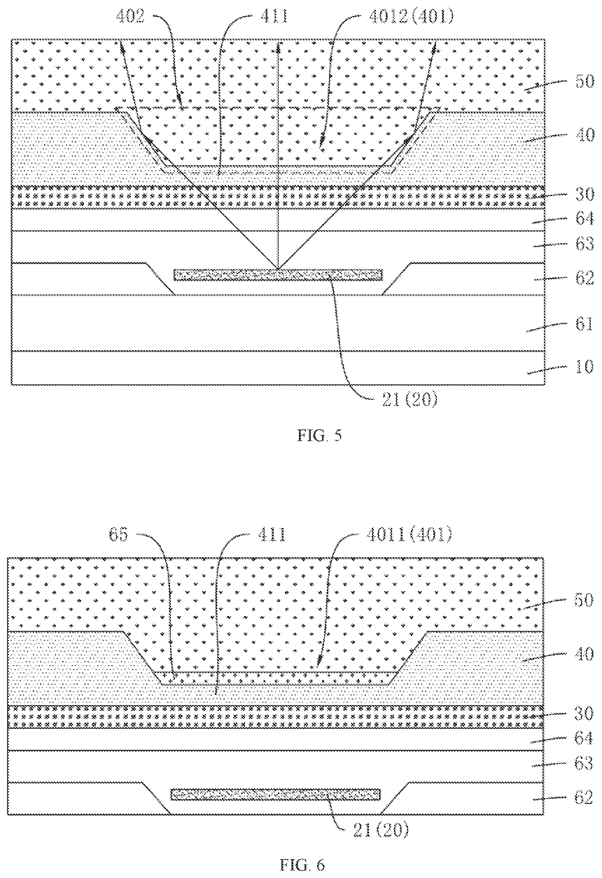

Referring to FIG. 5, an embodiment of the present disclosure provides a display panel including a substrate 10, a light-emitting functional layer 20, a spacer layer 30, a first refractive index layer 40, a second refractive index layer 50, and a refraction compensation portion 411.

The light-emitting functional layer 20 is disposed at a side of the substrate 10, and includes a plurality of light-emitting portions 21. The spacer layer 30 is provided at a side of the light-emitting functional layer 20 away from the substrate 10. The first refractive index layer 40 is provided at a side of the spacer layer 30 away from the light-emitting functional layer 20, and the first refractive index layer 40 is provided with a plurality of openings 401 corresponding to the plurality of light-emitting portions 21. The second refractive index layer 50 is disposed at a side of the first refractive index layer 40 away from the spacer layer 30, and the second refractive index layer 50 is filled in at least the plurality of openings 401, and a refractive index of the first refractive index layer 40 is less than a refractive index of the second refractive index layer 50.

Further, the display panel further includes a refraction compensation portion 411 disposed in the opening 401, the refraction compensation portion 411 is located between the second refractive index layer 50 and the spacer layer 30, and a refractive index of the refraction compensation portion 411 is less than that of the second refractive index layer 50, and the refractive index of the refraction compensation portion 411 is less than that of the spacer layer 30.

In application of an embodiment, the refraction compensation portion 411 in the embodiment of the present disclosure is provided in the opening 401 of the first refractive index layer 40, and the refractive index of the refraction compensation portion 411 is less than the refractive index of the spacer layer 30 and less than the refractive index of the second refractive index layer 50, so that a refractive index change similar to that in the opening 401 having the adhering layer is formed in each opening 401, and the refractive index changes formed in respective openings 401 tend to be consistent, thereby reducing the optical difference between the area with the adhering layer and the area without the adhering layer, effectively improving the display unevenness of the display panel, and improving the optical abnormality of the display panel.

In an embodiment of the present disclosure, both the first refractive index layer and the refraction compensation portion are located on a surface of the spacer layer away from the substrate.

In an embodiment of the present disclosure, the refractive index of the refraction compensation portion is greater than or equal to the refractive index of the first refractive index layer.

In an embodiment of the present disclosure, the opening penetrates through the first refractive index layer, the refraction compensation portion is connected to a sidewall of the opening, the opening penetrates through the first refractive index layer, the refraction compensation portion is connected to a sidewall of the opening, a surface of the refraction compensation portion away from the spacer layer is connected to the sidewall of the opening to form a groove, and a cross-sectional shape of the groove in a direction perpendicular to the substrate includes an inverted trapezoid.

In an embodiment of the present disclosure, the material of the first refractive index layer is the same as the material of the refraction compensation portion.

In an embodiment of the present disclosure, the first refractive index layer includes a first sub-layer and a second sub-layer that are stacked, and the first sub-layer is located between the spacer layer and the second sub-layer, the opening includes a first sub-opening penetrating through the first sub-layer and a second sub-opening penetrating through the second sub-layer, and the refraction compensation portion is disposed within the first sub-opening.

In an embodiment of the present disclosure, the refractive index of the refraction compensation portion is greater than or equal to the refractive index of the first sub-layer.

In an embodiment of the present disclosure, the refraction compensation portion is connected to a sidewall of the first sub-opening, the material of the refraction compensation portion is the same as that of the first sub-layer, and the material of the first sub-layer is the same as or different from that of the second sub-layer.

In an embodiment of the present disclosure, a cross-sectional shape of the opening in a direction perpendicular to the substrate includes an inverted trapezoidal shape, and an included angle between an inner wall of the opening and the refraction compensation portion is greater than 90° and less than or equal to 135°.

In an embodiment of the present disclosure, a thickness of the refraction compensation portion is less than or equal to half of the thickness of the first refractive index layer.

In an embodiment of the present disclosure, the second refractive index layer includes an adhesive layer coving a side of the first refractive index layer away from the spacer layer and filled in the opening.

In an embodiment of the present disclosure, a plurality of the openings include a first opening, the display panel further includes an adhering layer disposed within the first opening, and the adhering layer is disposed between at least a portion of the refraction compensation portion and the second refractive index layer.

In an embodiment of the present disclosure, the refractive index of the adhering layer is less than the refractive index of the second refractive index layer and less than the refractive index of the spacer layer.

In an embodiment of the present disclosure, an absolute value of a difference between the refractive index of the adhering layer and the refractive index of the refraction compensation portion is less than or equal to 0.1.

In an embodiment of the present disclosure, an absolute value of a difference between the refractive index of the adhering layer and the refractive index of the refraction compensation portion is less than or equal to 0.05.

In an embodiment of the present disclosure, the display panel further includes a touch electrode layer disposed between the light-emitting functional layer and the spacer layer, and the spacer layer covers the touch electrode layer.

In an embodiment of the present disclosure, the forming of a second refractive index layer at a side of the first refractive index layer away from the spacer layer includes following steps.

A protective film is formed at a side of the first refractive index layer away from the spacer layer, the protective film is formed with a protective layer and a bonding adhesive layer arranged in a stacked manner, and the protective layer is adhered to the side of the first refractive index layer away from the spacer layer through the bonding adhesive layer.

The protective film is removed, the bonding adhesive layer leaving in at least a portion of the opening forms an adhering layer, and the adhering layer has a refractive index less than that of the spacer layer.

A second refractive index layer is formed at a side of the first refractive index layer away from the spacer layer, the second refractive index layer is filled in a plurality of the openings, the adhering layer is positioned between the refraction compensation portion and the second refractive index layer, and the refractive index of the adhering layer is less than the refractive index of the second refractive index layer.

Continuing with reference to FIG. 5, in an embodiment, a display panel provided in an embodiment of the present disclosure includes a substrate 10, a thin film transistor layer 61 disposed on the substrate 10, a light-emitting functional layer 20 and a pixel definition layer 62 disposed at a side of the thin film transistor layer 61 away from the substrate 10, an encapsulation layer 63 disposed at a side of the light-emitting functional layer 20 away from the thin film transistor layer 61, a touch electrode layer 64 disposed at a side of the encapsulation layer 63 away from the light-emitting functional layer 20, a spacer layer 30 disposed at a side of the touch electrode layer 64 away from the encapsulation layer 63, a first refractive index layer 40 disposed at a side of the spacer layer 30 away from the touch electrode layer 64, and a second refractive index layer 50 disposed at a side of the first refractive index layer 40 away from the spacer layer 30.

The thin film transistor layer 61 includes a plurality of thin film transistors disposed on the substrate 10, a plurality of pixel openings are disposed in the pixel definition layer 62, and the light-emitting functional layer 20 includes a plurality of light-emitting portions 21 disposed in the plurality of pixel openings. The thin film transistors can serve as switches to control on/off of signals input to the light-emitting portions 21.

The encapsulation layer 63 covers the plurality of light-emitting portions 21 to provide protection and barrier to moisture and oxygen to the light-emitting functional layer 20. The encapsulation layer 63 may include a laminated structure of an inorganic layer and an organic layer.

The touch electrode layer 64 may include a plurality of touch electrodes and touch wires, and the touch electrode layer 64 may be provided in a mutual capacitive touch structure, or may be provided in a self-capacitive touch structure, which is not limited herein.

The first refractive index layer 40 is provided on the surface of the spacer layer 30 away from the substrate 10, a plurality of openings 401 are provided in the first refractive index layer 40, the plurality of openings 401 are provided corresponding to the plurality of light-emitting portions 21, and the openings 401 are provided to penetrate through the first refractive index layer 40.

In an embodiment, the plurality of openings 401 may be provided in one-to-one correspondence with the plurality of light-emitting portions 21, and an orthographic projection of a light-emitting portion 21 on the substrate 10 is located within an orthographic projection of a corresponding opening 401 on the substrate 10.

The second refractive index layer 50 fills at least the plurality of openings 401, and the refractive index of the second refractive index layer 50 is greater than the refractive index of the first refractive index layer 40, so as to change the light output path of the display panel at the interface between the first refractive index layer 40 and the second refractive index layer 50 based on the total reflection principle, converge the light originally diverged at the large viewing angle to the front viewing angle, and improve the brightness at the front viewing angle.

In an embodiment, when the display panel is not a polarizer free (POL-less (PLP)) display panel, the spacer layer 30 covers the touch electrode layer 64, and optionally, the material of the spacer layer 30 may include a silicon nitride material. In addition, the display panel further includes a polarizer disposed at a side of the second refractive index layer 50 away from the first refractive index layer 40.

Here, the second refractive index layer 50 may include an adhesive layer having a high refractive index, and the adhesive layer covers a side of the first refractive index layer 40 away from the spacer layer 30 and fills in the opening 401, so that the polarizer may be attached to a side of the first refractive index layer 40 away from the spacer layer 30 through the second refractive index layer 50.

In another embodiment, when the display panel is a polarizer free display panel, the spacer layer 30 is a color film layer (or a filter layer), and an insulating layer may be provided between the spacer layer 30 and the touch electrode layer 64 as a spacer. The spacer layer 30 may include a plurality of color blocks and a light shielding structure provided between adjacent color blocks, the plurality of color blocks may be provided in one-to-one correspondence with the plurality of light-emitting portions 21, and the color of each color block is the same as the color of the emitted light of a corresponding light-emitting portion 21. The light shielding structure may include a black matrix, or stacked color blocks of different colors, or other materials for shielding. In addition, the display panel further includes a cover plate provided at a side of the second refractive index layer 50 away from the first refractive index layer 40.

Similarly, when the second refractive index layer 50 is an adhesive layer having a high refractive index, the cover plate may be attached to a side of the first refractive index layer 40 away from the spacer layer 30 by the second refractive index layer 50.

It will be appreciated that the second refractive index layer 50 is formed in the embodiment of the present disclosure using an adhesive layer having a high refractive index, and may be adhered to the polarizing plate or the cover plate so as to reduce the number of the adhesive layers in the display panel, thereby reducing a thickness of the display panel, and improving the lightness and thinning of the display panel.

Further, in an embodiment, referring to FIGS. 5 and 6, the plurality of openings 401 include a first opening 4011 and a second opening 4012. The display panel further includes an adhering layer 65 disposed in the first opening 4011. It may be understood that the adhering layer 65 is an adhesive layer material remaining after the protective film is torn off in the process, and the opening 401 in which the adhering layer 65 is formed is the first opening 4011, and the opening 401 in which the adhering layer 65 is not formed is the second opening 4012.

It should be noted that the shape and position of the adhering layer 65 in the first opening 4011 are not limited, for example, the adhering layer 65 may be located at the sidewall and/or bottom of the first opening 4011, and may cover a part or all of the sidewall, or may cover a part or all of the bottom, and in an illustration of the present disclosure, the embodiment of the adhering layer 65 covering the bottom of the first opening 4011 is taken as an example to illustrate.

Here, the refractive index of the adhering layer 65 is small, and the refractive index of the adhering layer 65 is small, generally less than 1.5, for example, may be 1.45, so that the refractive index change process of the film layer structure at the first opening 4011 is changed, and the refractive index change process of the film layer structure at the first opening 4011 is different from the refractive index change process of the film layer structure at the second opening 4012, thereby causing an optical anomaly, such as uneven display, of the display panel.

In view of the problem in the related art that the adhering layer 65 causes an optical abnormality, in the embodiment of the present disclosure, the display panel further includes a refraction compensation portion 411 provided at the bottom of the opening 401, and the refraction compensation portion 411 is located between the spacer layer 30 and the second refractive index layer 50. The refraction compensation portion 411 is located on the surface of the spacer layer 30 away from the substrate 10, and in the first opening 4011, the adhering layer 65 covers the surface of the refraction compensation portion 411 away from the spacer layer 30. The second refractive index layer 50 covers the surface of the adhering layer 65 away from the refraction compensation portion 411. In the second opening 4012, the second refractive index layer 50 covers the surface of the refraction compensation portion 411 away from the spacer layer 30.

It may be appreciated that the embodiment of the present disclosure may form the refraction compensation portion 411 at the bottom of each opening 401 of the display panel, that is, the refraction compensation portion 411 is formed at the bottom of each of the first opening 4011 and the second opening 4012.

The refractive index of the refraction compensation portion 411 is less than the refractive index of the spacer layer 30, and the refractive index of the refraction compensation portion 411 is also less than the refractive index of the second refractive index layer 50, so that the refractive index change process of the film structure at the first opening 4011 is similar to the refractive index change process of the film structure at the second opening 4012, thereby reducing the optical difference between the region corresponding to the first opening 4011 and the second opening 4012, and improving the display uniformity of the display panel.

It should be noted that the refraction compensating portion 411 may cover a part of the area at the bottom of the opening 401, or may cover all of the area at the bottom of the opening 401. In the illustration provided in the present disclosure, the refraction compensating portion 411 may cover all of the area at the bottom of the opening 401 as an example.

Referring to FIG. 5, the opening 401 penetrates through the first refractive index layer 40, and the refraction compensation portion 411 is connected to the sidewall of the opening 401, and the surface of the refraction compensation portion 411 away from the spacer layer 30 is connected to the sidewall of the opening 401 to form the groove 402. In an embodiment, the cross-sectional shape of the groove 402 in the direction perpendicular to the substrate 10 includes an inverted trapezoidal shape.

In an embodiment, the refractive index of the refraction compensation portion 411 is similar to the refractive index of the adhering layer 65, and the absolute value of the difference between the refractive index of the refraction compensation portion 411 and the refractive index of the adhering layer 65 is less than or equal to 0.1. Further, preferably, the absolute value of the difference between the refractive index of the refraction compensation portion 411 and the refractive index of the adhering layer 65 is less than or equal to 0.05 to further reduce the optical difference between the region corresponding to the first opening 4011 and the second opening 4012.

In an embodiment, the refractive index of the refraction compensation portion 411 may be less than or equal to 1.5, and both the refractive index of the spacer layer 30 and the refractive index of the second refractive index layer 50 may be greater than 1.5, for example, the refractive index of the spacer layer 30 and the refractive index of the second refractive index layer 50 may be each independently 1.55, 1.6, 1.65, 1.7, 1.75, 1.8, 1.85, 1.9, 1.95, or the like.

In an embodiment, the material of the refraction compensation portion 411 may include acrylic or siloxane compound, the material of the adhering layer 65 may include acrylic or silica gel, and the material of the refraction compensation portion 411 may be the same as the material of the adhering layer 65.

In an embodiment of the present disclosure, referring to FIG. 5, the refractive compensation portion 411 is located at the bottom of the opening 401 and is connected to the first refractive index layer 40, that is, the refractive compensation portion 411 is connected to the sidewall of the opening 401 of the first refractive index layer 40, and the material of the refractive compensation portion 411 may be the same as that of the first refractive index layer 40. That is, the refractive compensation portion 411 may be integrally formed with the first refractive index layer 40.

It should be noted that the refraction compensation portion 411 and the first refractive index layer 40 may be formed in the same photomask process to save the process. In other embodiments, the refraction compensation portion 411 and the first refractive index layer 40 may be formed by two photomask processes, respectively.

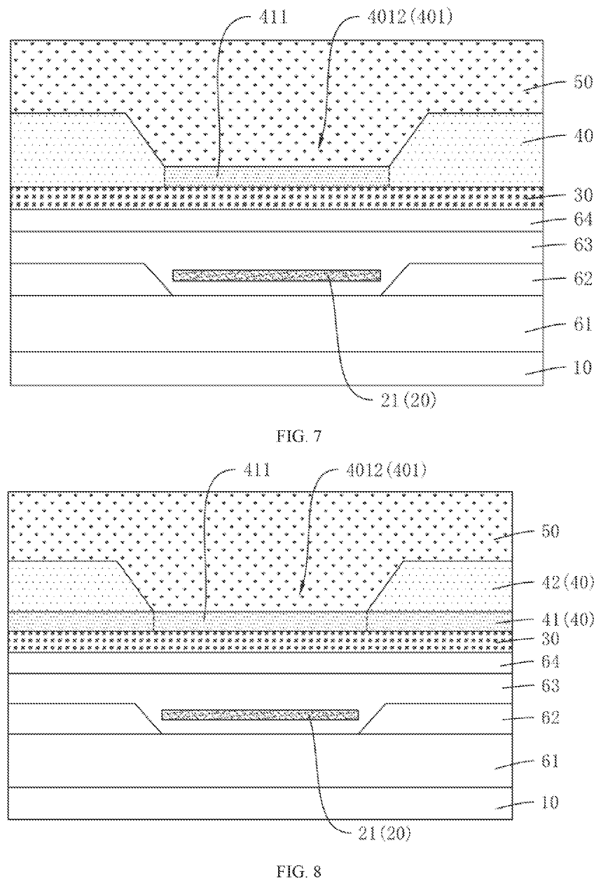

In a modified example corresponding to FIG. 5, referring to FIG. 7, the refractive compensation portion 411 is provided at the bottom of the opening 401 and connected to the first refractive index layer 40, and the material of the refractive compensation portion 411 is different from that of the first refractive index layer 40.

In an embodiment, the refractive index of the refraction compensation portion 411 is greater than or equal to the refractive index of the first refractive index layer 40, and when the refractive index of the refraction compensation portion 411 is equal to the refractive index of the first refractive index layer 40, the refraction compensation portion 411 and the first refractive index layer 40 can be manufactured in the same process to save the mask and reduce the cost. When the refractive index of the refraction compensating portion 411 is greater than the refractive index of the first refractive index layer 40, the refractive index difference interface similar to the interface between the first refractive index layer 40 and the second refractive index layer 50 may be formed at the sidewall where the refractive index compensating portion 411 is connected in the opening 401, so as to improve the light gathering effect and further improve the light output efficiency.

In another embodiment of the present disclosure, referring to FIG. 8, the first refractive index layer 40 includes a first sub-layer 41 and a second sub-layer 42 disposed in a stacked manner, the first sub-layer 41 is disposed between the spacer layer 30 and the second sub-layer 42, and the refraction compensation portion 411 is disposed at the bottom of the opening 401 and connected to the first sub-layer 41.

Specifically, the opening 401 penetrates through the first sub-layer 41 and the second sub-layer 42, the opening 401 includes a first sub-opening penetrating through the first sub-layer 41 and a second sub-opening penetrating through the second sub-layer 42, and the refraction compensation portion 411 is disposed in the first sub-opening and connected to the sidewall of the first sub-opening, that is, to the first sub-layer 41.

In the present embodiment, the refraction compensation portion 411 includes the same material as the first sub-layer 41, that is, the refraction compensation portion 411 is formed integrally with the first sub-layer 41. In addition, the material of the first sub-layer 41 may be the same as or different from that of the second sub-layer 42, and the refractive index of the first sub-layer 41 and the refractive index of the second sub-layer 42 are both less than that of the second refractive index layer 50, which is not limited herein.

It should be noted that the refraction compensation portion 411 and the first sub-layer 41 may be formed in the same photomask process to save the process. In other embodiments, the refraction compensation portion 411 and the first sub-layer 41 may be formed by two photomask processes, respectively.

In a modified example corresponding to FIG. 8, the material of the refraction compensation portion 411 may be different from the material of the first sub-layer 41.

In an embodiment, the refractive index of the refraction compensation portion 411 is greater than or equal to the refractive index of the first sub-layer 41, and when the refractive index of the refraction compensation portion 411 is equal to the refractive index of the first sub-layer 41, the refraction compensation portion 411 and the first sub-layer 41 can be manufactured in the same process to save the mask and reduce the cost. When the refractive index of the refraction compensation portion 411 is greater than the refractive index of the first sub-layer 41, the refractive index difference interface similar to the interface between the first refractive index layer 40 and the second refractive index layer 50 may be formed at the sidewall where the refraction compensation portion 411 is connected in the opening 401, so as to improve the light gathering effect and further improve the light output efficiency.

Further, the cross-sectional shape of the opening 401 in the direction perpendicular to the substrate 10 includes an inverted trapezoidal shape, and the included angle between the refraction compensation portion 411 and the sidewall of the opening 401 is greater than 90° and less than or equal to 135°, so that the light path is adjusted to a desired light output angle.

In an embodiment, in order to avoid that the depth of the opening 401 is excessively small due to the excessive thickness of the refraction compensation portion 411, and the optical path adjustment effect between the first refractive index layer 40 and the second refractive index layer 50 is greatly affected, therefore, the thickness of the refraction compensation portion 411 is less than or equal to one half of the thickness of the first refractive index layer 40.

In this embodiment of the present disclosure, the refraction compensation portion 411 is provided at the bottom of the opening 401 of the first refractive index layer 40, and the refractive index of the refraction compensation portion 411 is less than the refractive index of the spacer layer 30 and less than the refractive index of the second refractive index layer 50, so that a refractive index change process similar to that of the opening 401 having the adhering layer 65 is formed in each opening 401, thereby reducing the optical difference between the region with the adhering layer 65 and the region without the adhering layer 65, effectively improving the display unevenness of the display panel, and improving the optical abnormality of the display panel.

In addition, referring to FIGS. 5 to 11, an embodiment of the present invention further provides a method for manufacturing a display panel, the method includes the following steps.

At step S10, a light-emitting functional layer 20 is formed above the substrate 10, and a plurality of light-emitting portions 21 are formed in the light-emitting functional layer 20.

At step S20, a spacer layer 30 is formed at a side of the light-emitting functional layer 20 away from the substrate 10.

At step S30, a first refractive index layer 40 in which a plurality of openings 401 corresponding to the plurality of light-emitting portions 21 are formed and a refraction compensation portion 411 formed at the bottom of the openings 401 are formed at the side of the spacer layer 30 away from the light-emitting functional layer 20, and the refraction compensation portion 411 has a refractive index less than that of the spacer layer 30.

At step S40, a second refractive index layer 50 is formed at a side of the first refractive index layer 40 away from the spacer layer 30, the second refractive index layer 50 is filled in the plurality of openings 401, the refractive index of the first refractive index layer 40 is less than the refractive index of the second refractive index layer 50, the refraction compensation portion 411 is located between the spacer layer 30 and the second refractive index layer 50, and the refractive index of the refraction compensation portion 411 is less than the refractive index of the second refractive index layer 50.

In step S10, the substrate 10 is first provided, and then the thin film transistor layer 61, and the pixel definition layer 62 and the light-emitting functional layer 20 located on the side of the thin film transistor layer 61 away from the substrate 10 are sequentially formed on the substrate 10.

Here, the thin film transistor layer 61 includes a plurality of thin film transistors formed on the substrate 10, a plurality of pixel openings are formed in the pixel definition layer 62, and the light-emitting functional layer 20 includes a plurality of light-emitting portions 21 formed in the plurality of pixel openings. The thin film transistors can serve as switches to control on/off of signals input to the light-emitting portions 21.

Next, an encapsulation layer 63 is formed at a side of the light-emitting functional layer 20 and the pixel definition layer 62 away from the substrate 10, the encapsulation layer 63 covers the light-emitting functional layer 20 and the pixel definition layer 62, and the encapsulation layer 63 may include a inorganic layer and an organic layer that are stacked. The inorganic layer may include a silicon nitride or silicon oxide to serve as a barrier to moisture and oxygen, and the organic layer may include an organic resin material to serve as a buffer stress.

In step S20, a touch electrode layer 64 is formed at a side of the encapsulation layer 63 away from the light-emitting functional layer 20, the touch electrode layer 64 may include a plurality of touch electrodes and touch wires, and the touch electrode layer 64 may be arranged in a mutual capacitive touch structure, or may be arranged in a self-capacitive touch structure, which is not limited herein.

Then, a spacer layer 30 is formed at the side of the touch electrode layer 64 away from the light-emitting functional layer 20, and the spacer layer 30 is an insulating film layer covering the touch electrode layer 64, for example, the material of the spacer layer 30 may be a silicon nitride.

In step S30, the first refractive index layer 40 and the refraction compensation portion 411 are formed at the side of the spacer layer 30 away from the light-emitting functional layer 20, and the refractive index of the refraction compensation portion 411 is less than the refractive index of the spacer layer 30, for example, the refractive index of the refraction compensation portion 411 is less than or equal to 1.5.

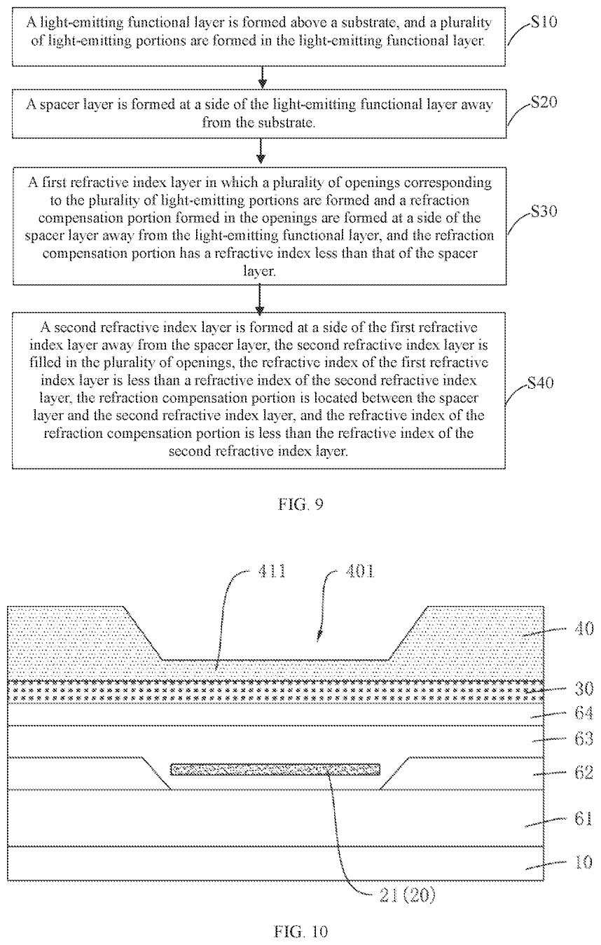

In an embodiment, as shown in FIG. 10, the first material layer may be first formed of a material having a refractive index satisfying a requirement, and the first material layer may be patterned using a semi-transparent mask plate to form the first refractive index layer 40 and the refraction compensation portion 411 integrally formed. The refraction compensation portion 411 is correspondingly formed by removing a region having a larger thickness, and the first refractive index layer 40 is correspondingly formed by removing a region having a smaller thickness.

In a modified example corresponding to FIG. 10, as shown in FIG. 7, a second material layer is formed at the side of the spacer layer 30 away from the light-emitting functional layer 20, and the second material layer is patterned to form the opening 401 corresponding to the light-emitting portion 21, thereby obtaining the first refractive index layer 40. Then, a third material layer is formed on the first refractive index layer 40, and the third material layer is patterned to form the refraction compensation portion 411 at the bottom of the opening 401.

It should be noted that, in the display panel shown in FIG. 7, a third material layer may be first formed and patterned to obtain the refraction compensation portion 411 corresponding to the light-emitting portion 21, and then a second material layer covering the refraction compensation portion 411 is formed and patterned to form the opening 401 exposing an upper surface of the refraction compensation portion 411.

In an embodiment, as shown in FIG. 8, a fourth material layer may be formed of a material having a refractive index satisfying a requirement, then a fifth material layer is formed on the fourth material layer, and the fifth material layer is patterned, that is, a second sub-opening is formed at a position where the fifth material layer corresponds to the light-emitting portion 21, and the fourth material layer forms a first sub-layer 41 and a refraction compensation portion 411 integrally formed. The fifth material layer forms a second sub-layer 42, and the first sub-layer 41 and the second sub-layer 42 are laminated to form the first refractive index layer 40.

In a modified example corresponding to FIG. 8, the refraction compensation portion 411 and the first sub-layer 41 have different materials, that is, a fourth material layer may be first formed and patterned to form the first sub-opening at a position corresponding to the light-emitting portion 21 to obtain the first sub-layer 41. A refraction compensation portion 411 is then formed in the first sub-opening; Then, a fifth material layer is formed on the first sub-layer 41 and the refraction compensation portion 411, and the fifth material layer is patterned to form a second sub-opening corresponding to the first sub-opening, and the second sub-opening exposes the refraction compensation portion 411.

In the embodiment of the present disclosure, the structures shown in FIG. 5 and FIG. 10 are used as an example to describe a subsequent process.

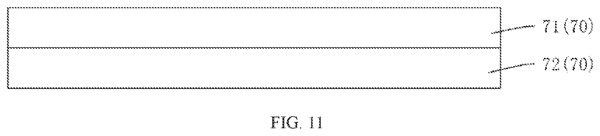

In step S40, after the opening 401 is formed in the first refractive index layer 40, the display panel may undergo a plurality of processes such as handling, flipping, cutting, and slitting. Therefore, in the embodiment of the present disclosure, the protective film 70 is formed at the side of the first refractive index layer 40 away from the spacer layer 30, and the structure of the protective film 70 is shown in FIG. 11.

The protective film 70 includes a protective layer 71 and a bonding adhesive layer 72, and a side of the protective film 70 provided with the bonding adhesive layer 72 is attached to a side of the first refractive index layer 40 away from the spacer layer 30, so that the protective film 70 is attached to the first refractive index layer 40.

Next, the protective film 70 is removed. Since the bonding adhesive layer 72 of the protective film 70 is adhesive, it is prone to remain in the opening 401 of the first refractive index layer 40, that is, after the protective film 70 is removed, the bonding adhesive layer 72 may remain in at least part of the opening 401, and the residual bonding adhesive layer 72 forms the adhering layer 65, and the refractive index of the adhering layer 65 is less than the refractive index of the spacer layer 30.

In an embodiment, referring to FIGS. 5 and 6, the plurality of openings 401 includes a first opening 4011 and a second opening 4012. The display panel further includes an adhering layer 65 disposed in the first opening 4011. It is understood that the adhering layer 65 is an adhesive layer material remaining after the protective film 70 is torn off in the process, the opening 401 in which the adhering layer 65 is formed is the first opening 4011, and the opening 401 in which the adhering layer 65 is not formed is the second opening 4012.

It should be noted that the shape and position of the adhering layer 65 in the first opening 4011 are not limited, and may be located, for example, at the sidewall and/or bottom of the first opening 4011, and may cover a part or all of the sidewall, or may cover a part or all of the bottom, and in an illustration of the present disclosure, the embodiment of the adhering layer 65 covering the bottom of the first opening 4011 is taken as an example to illustrate.

Next, a second refractive index layer 50 is formed at a side of the first refractive index layer 40 away from the spacer layer 30, and the second refractive index layer 50 fills the plurality of openings 401 and covers the surface of the first refractive index layer 40 away from the spacer layer 30. The refractive index of the first refractive index layer 40 is less than the refractive index of the second refractive index layer 50, and the refractive index of the refraction compensation portion 411 is less than the refractive index of the second refractive index layer 50.

In an embodiment, the second refractive index layer 50 may be a layer of adhesive having a high refractive index, and the adhesive layer is attached to a side of the first refractive index layer 40 away from the spacer layer 30, and the adhesive layer is further filled in the opening 401 to form the second refractive index layer 50.

In the first opening 4011, the adhering layer 65 covers the surface of the refraction compensation portion 411 away from the spacer layer 30, and the second refractive index layer 50 covers the surface of the adhering layer 65 away from the refraction compensation portion 411. In the second opening 4012, the second refractive index layer 50 covers the surface of the refraction compensation portion 411 away from the spacer layer 30.

In view of the problem that the adhering layer 65 in the related art causes optical abnormalities, in an embodiment of the present disclosure, the display panel further includes a refraction compensation portion 411 disposed at the bottom of the opening 401, the refraction compensation portion 411 is disposed between the spacer layer 30 and the second refractive index layer 50, both the refraction compensation portion 411 and the adhering layer 65 have a refractive index less than the refractive index of the spacer layer 30, and both the refraction compensation portion 411 and the adhering layer 65 have a refractive index less than the refractive index of the second refractive index layer 50, so that the refractive index change process of the film layer structure at the first opening 4011 is similar to the refractive index change process of the film layer structure at the second opening 4012, thereby reducing the optical difference between the region corresponding to the first opening 4011 and the second opening 4012, and improving display uniformity of the display panel.

In an embodiment, the refractive index of the refraction compensation portion 411 is similar to the refractive index of the adhering layer 65, and the absolute value of the difference between the refractive index of the refraction compensation portion 411 and the refractive index of the adhering layer 65 is less than or equal to 0.1. Further, preferably, the absolute value of the difference between the refractive index of the refraction compensation portion 411 and the refractive index of the adhering layer 65 is less than or equal to 0.05 to further reduce the optical difference between the region corresponding to the first opening 4011 and the second opening 4012.

In an embodiment, the refractive index of the refraction compensation portion 411 may be less than or equal to 1.5, and both the refractive index of the spacer layer 30 and the refractive index of the second refractive index layer 50 may be greater than 1.5, for example, the refractive index of the spacer layer 30 and the refractive index of the second refractive index layer 50 may be each independently 1.55, 1.6, 1.65, 1.7, 1.75, 1.8, 1.85, 1.9, 1.95, or the like.

In an embodiment, the material of the refraction compensation portion 411 may include acrylic or siloxane compound, the material of the adhering layer 65 may include acrylic or silica gel, and the material of the refraction compensation portion 411 may be the same as the material of the adhering layer 65.

In summary, in the present embodiment, the refraction compensation portion 411 is provided at the bottom of the opening 401 of the first refractive index layer 40, and the refractive index of the refraction compensation portion 411 is less than the refractive index of the spacer layer 30 and less than the refractive index of the second refractive index layer 50, so that a refractive index change process similar to that of the opening 401 with the adhering layer 65 is formed in each opening 401, thereby reducing the optical difference between the region with the adhering layer 65 and the region without the adhering layer 65, effectively improving the display unevenness of the display panel, and improving the optical abnormality of the display panel.

In addition, an embodiment of the present disclosure further provides a display device including the display panel described in the above embodiment.

In an embodiment, the display device may include a display device such as a mobile phone, a television, a computer, a tablet, or the like.

It may be appreciated that since the display device includes the display panel described in the above embodiment, the display device has the same beneficial effect as the display panel in the above embodiment.

In the above-mentioned embodiments, the description of each embodiment has its own emphasis, and parts not described in detail in a certain embodiment may be referred to the related description of other embodiments.

The display panel, the method for manufacturing the same, and the display device according to the embodiments of the present disclosure are described in detail above. The principles and embodiments of the present disclosure are described herein with reference to specific embodiments. The description of the above embodiments is merely intended to assist in understanding the technical solution of the present disclosure and the core concepts thereof. It may be appreciated by those ordinary skilled in the art that modifications may still be made to the technical solutions described in the foregoing embodiments, or equivalent replacements may be made to some of the technical features therein. These modifications or substitutions do not cause the essence of the corresponding technical solutions to deviate from the scope of the technical solutions of the embodiments of the present disclosure.

What is claimed is:

1. A display panel comprising:
a substrate;
a light-emitting functional layer disposed at a side of the substrate, the light-emitting functional layer including a plurality of light-emitting portions;
a spacer layer disposed at a side of the light-emitting functional layer away from the substrate;
a first refractive index layer disposed at a side of the spacer layer away from the light-emitting functional layer, the first refractive index layer being provided with a plurality of openings corresponding to the plurality of light-emitting portions; and
a second refractive index layer disposed at a side of the first refractive index layer away from the spacer layer and filled within at least a plurality of the openings, a refractive index of the first refractive index layer being less than a refractive index of the second refractive index layer;
wherein the display panel further comprises a refraction compensation portion disposed in an opening of the plurality of openings, the refraction compensation portion is disposed between the second refractive index layer and the spacer layer, a refractive index of the refraction compensation portion is less than the refractive index of the second refractive index layer, and the refractive index of the refraction compensation portion is less than a refractive index of the spacer layer.

2. The display panel according to claim 1, wherein the first refractive index layer and the refraction compensation portion are both located on a surface of the spacer layer away from the substrate.

3. The display panel according to claim 2, wherein the refractive index of the refraction compensation portion is greater than or equal to the refractive index of the first refractive index layer.

4. The display panel according to claim 2, wherein the opening penetrates through the first refractive index layer, the refraction compensation portion is connected to a sidewall of the opening, a surface of the refraction compensation portion away from the spacer layer is connected to the sidewall of the opening to form a groove, and a cross-sectional shape of the groove in a direction perpendicular to the substrate comprises an inverted trapezoid.

5. The display panel according to claim 4, wherein a material of the first refractive index layer is a same as a material of the refraction compensation portion.

6. The display panel according to claim 2, wherein the first refractive index layer comprises a first sub-layer and a second sub-layer disposed in a stacked manner, the first sub-layer is located between the spacer layer and the second sub-layer, the opening comprises a first sub-opening penetrating through the first sub-layer and a second sub-opening penetrating through the second sub-layer, and the refraction compensation portion is disposed in the first sub-opening.

7. The display panel according to claim 6, wherein the refractive index of the refraction compensation portion is greater than or equal to a refractive index of the first sub-layer.

8. The display panel according to claim 6, wherein the refraction compensation portion is connected to a sidewall of the first sub-opening, a material of the refraction compensation portion is a same as a material of the first sub-layer, and the material of the first sub-layer is a same as or different from a material of the second sub-layer.

9. The display panel according to claim 2, wherein a cross-sectional shape of the opening in a direction perpendicular to the substrate comprises an inverted trapezoid, and an included angle between an inner wall of the opening and the refraction compensation portion is greater than 90° and less than or equal to 135°.

10. The display panel according to claim 1, wherein a thickness of the refraction compensation portion is less than or equal to one half of a thickness of the first refractive index layer.

11. The display panel according to claim 1, wherein the second refractive index layer comprises a adhesive layer covering a side of the first refractive index layer away from the spacer layer and filled in the opening.

12. The display panel according to claim 1, wherein the plurality of openings comprises a first opening, the display panel further comprises an adhering layer disposed in the first opening, and the adhering layer is disposed between at least a portion of the refraction compensation portion and the second refractive index layer.

13. The display panel according to claim 12, wherein a refractive index of the adhering layer is less than the refractive index of the second refractive index layer and less than the refractive index of the spacer layer.

14. The display panel according to claim 12, wherein an absolute value of a difference between the refractive index of the adhering layer and the refractive index of the refraction compensation portion is less than or equal to 0.1.

15. The display panel according to claim 12, wherein an absolute value of a difference between the refractive index of the adhering layer and the refractive index of the refraction compensation portion is less than or equal to 0.05.

16. The display panel according to claim 1, wherein the display panel further comprises a touch electrode layer disposed between the light-emitting functional layer and the spacer layer, and the spacer layer covers the touch electrode layer.

17. A method of manufacturing a display panel, comprising:
forming a light-emitting functional layer on a substrate, wherein a plurality of light-emitting portions are formed in the light-emitting functional layer;
forming a spacer layer on a side of the light-emitting functional layer away from the substrate;
forming a first refractive index layer and a refraction compensation portion at a side of the spacer layer away from the light-emitting functional layer, wherein a plurality of openings corresponding to the plurality of light-emitting portions are formed in the first refractive index layer, the refraction compensation portion is formed in the openings, and the refraction compensation portion has a refractive index less than a refractive index of the spacer layer; and
forming a second refractive index layer at a side of the first refractive index layer away from the spacer layer, the second refractive index layer filling the plurality of the openings, a refractive index of the first refractive index layer being less than a refractive index of the second refractive index layer, the refraction compensation portion being located between the spacer layer and the second refractive index layer, and the refractive index of the refraction compensation portion being less than the refractive index of the second refractive index layer.

18. The method according to claim 17, wherein the forming of the second refractive index layer at the side of the first refractive index layer away from the spacer layer comprises:
forming a protective film at the side of the first refractive index layer away from the spacer layer, the protective film being provided with a protective layer and a bonding adhesive layer arranged in a stacked manner, and the protective layer being adhered to the side of the first refractive index layer away from the spacer layer through the bonding adhesive layer;
removing the protective film, and leaving the bonding adhesive layer in at least a portion of the opening to form an adhering layer, the adhering layer having a refractive index less than the refractive index of the spacer layer;
forming a second refractive index layer at a side of the first refractive index layer away from the spacer layer, and the second refractive index layer being filled in the plurality of the openings, the adhering layer being positioned between the refraction compensation portion and the second refractive index layer, a refractive index of the adhering layer being less than the refractive index of the second refractive index layer.

19. A display device comprising a display panel, wherein the display panel comprises:
a substrate;
a light-emitting functional layer disposed at a side of the substrate, the light-emitting functional layer including a plurality of light-emitting portions;
a spacer layer disposed at a side of the light-emitting functional layer away from the substrate;
a first refractive index layer disposed at a side of the spacer layer away from the light-emitting functional layer, the first refractive index layer being provided with a plurality of openings corresponding to the plurality of light-emitting portions; and
a second refractive index layer disposed at a side of the first refractive index layer away from the spacer layer and filled within at least a plurality of the openings, a refractive index of the first refractive index layer being less than a refractive index of the second refractive index layer;
wherein the display panel further comprises a refraction compensation portion disposed in an opening of the plurality of openings, the refraction compensation portion is disposed between the second refractive index layer and the spacer layer, a refractive index of the refraction compensation portion is less than the refractive index of the second refractive index layer, and the refractive index of the refraction compensation portion is less than a refractive index of the spacer layer.

20. The display device according to claim 19, wherein the first refractive index layer and the refraction compensation portion are both located on a surface of the spacer layer away from the substrate.
